(19) United States
(12) Patent Application Publication
(10) Pub. No.: US 2026/0362882 A1
(43) Pub. Date: Nov. 12, 2026

(54) MICRODISPLAY PANEL AND MANUFACTURING METHOD THEREOF

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/404,041

(22) Filed: Dec. 1, 2025

(30) Foreign Application Priority Data
Dec. 27, 2024 (KR) 10-2024-0198795
Mar. 5, 2025 (KR) 10-2025-0028098

(51) Int. Cl. H10H 29/49; H10H 20/01; H10H 29/01; H10H 29/80

(52) U.S. Cl. CPC H10H 29/49; H10H 20/017; H10H 20/018; H10H 29/012; H10H 29/962

(57) ABSTRACT

The present invention relates to a microdisplay panel including: a back wafer in which a plurality of complementary metal-oxide semiconductor (CMOS) panel electrode dies are aligned on an upper surface; a plurality of light-emitting diode (LED) stacks aligned on the plurality of CMOS panel electrode dies; and a common electrode formed on the plurality of LED stacks, wherein each of the LED stacks includes a metal layer and a light-emitting portion stacked on the metal layer, the metal layer includes a first metal layer and a second metal layer, and the first metal layer is disposed on at least one of an upper portion and a lower portion of the second metal layer.

### CROSS-REFERENCE TO RELATED APPLICATION

This application claims priority to and the benefit of Korean Patent Application No. 10-2024-0198795, filed on Dec. 27, 2024, and Korean Patent Application No. 10-2025-0028098, filed on Mar. 5, 2025, the disclosure of which is incorporated herein by reference in its entirety.

### BACKGROUND

### 1. Field of the Invention

The present invention relates to a microdisplay panel and a method of manufacturing the same, and more particularly, to a light-emitting diode on silicon (LEDoS) microdisplay panel and a method of manufacturing the same, which do not require an alignment process of an LED stack and a complementary metal-oxide semiconductor (CMOS) panel electrode die through an engineering monolithic epitaxy wafer using a ceramic material when a front wafer and a back wafer are bonded.

### 2. Discussion of Related Art

The types of implementations of the metaverse, which has recently been attracting attention, are classified into four types of virtual reality (VR), augmented reality (AR), mixed reality (MR), and extended reality (XR). The metaverse ecosystem is expected to develop in the future focusing on XR, which is a reality that combines VR, AR, and MR among these. In addition, in order to implement this effectively, devices (smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a microdisplay panel 10 according to the related art corresponds to a technology that combines a silicon complementary metal-oxide-semiconductor (Si CMOS) semiconductor wafer process and a high-resolution, high-brightness, ultra-small display process, and the microdisplay panel 10 according to the related art may have a structure in which a Si CMOS wafer 11 of 4″ or more that has a (100) crystal plane and includes a plurality of CMOS panel electrode dies 12, a plurality of microLED electrode pads 14, and a transparent wafer 13 of 4″ or more that includes a plurality of microLED chips 15 are bonded through conductive bonding 16. Meanwhile, the types of microdisplay panels expected to be applied to XR devices include liquid crystal (LC)-based LC on Si (LCOS), organic light-emitting diode (OLED)-based OLED on Si (OLEDoS), and ultra-small microLED-based LED on Si (LEDoS) with a pixel size of less than 5 μm. In addition, in the case of VR, where displays with a low pixel density are applied, microdisplay panels are being developed and mass-produced mainly based on LCOS and OLEDoS.

However, with the advancement of metaverse implementation technology, the need for lightweight AR, MR, and XR devices to which microdisplay panels with a high pixel density are applied is gradually increasing. In addition, although the development of LEDoS technology, which is considered an ideal solution in theory based on its superior inorganic properties, is urgently needed to satisfy these needs, a microdisplay panel platform for this has not yet been established.

LEDoSs based on ultra-small microLEDs with pixel sizes of less than 5 μm have the advantages of an excellent power-to-performance ratio (P/P) and a short response speed when applied to XR devices, and there are the advantages that the LEDoSs include inorganic materials and thus have a long lifetime, and have efficient power use to reduce heat generation and enable long-term battery life. Particularly, since XR devices have a very short distance between the display and the eyes, even a slight delay in image conversion can easily cause discomfort such as dizziness. Thus, LEDoS, which has a nanosecond response speed, is considered to be the most suitable for XR devices compared to LCOS and OLEDoS, which have a microsecond response speed.

Furthermore, it is evaluated that the biggest reason why LEDoS is attracting attention in AR, MR, and XR devices, unlike VR, is due to its brightness and luminous efficiency. Since smart glasses can be worn in any location, high brightness is essential for normal operation even in outdoor environments such as in sunlight. In theory, microLEDs support brightness of tens to millions of nits, and since OLEDs are made of organic materials, whereas microLEDs are made of inorganic materials, the microLEDs also have the advantage of high luminous efficiency.

However, despite the above-described advantages, the biggest reason why LEDoSs based on ultra-small microLEDs with pixel sizes of less than 5 μm have not been established as a major component of XR devices is the difficulty in mass production. That is, since the LEDoS requires millions of ultra-small microLEDs to be fixed on a Si CMOS wafer, the process difficulty is high and the yield is very low, which leads to increased manufacturing costs and high component prices. This is reflected in the final consumer price, and it is difficult to satisfy market demand when LEDoSs are supplied as high-priced XR devices.

Meanwhile, as shown in FIG. 2, the development of LEDoS to which group III-V compound (GaN, GaP, and the like) microLED light sources are applied has been in progress until recently through traditional approaches such as (1) monolithic integration of wafers (or unit dies) including microLED arrays on CMOS wafers or (2) hybridization between wafers (or unit dies) on blue, green, and red light source wafers (or unit dies) on which wafers or microLED arrays are fabricated.

One of the biggest obstacles to the development of LEDoS to which blue, green, and red microLED light sources including group III-V compounds are applied is the difficulty in securing a solution for pixels smaller than 5 μm. In addition, recently, 5 μm-level pixels have been successfully demonstrated using monolithic integration technology, and some demonstrators developed based on hybridization technology were fabricated using sapphire flip chips, achieving 10 μm-level pixels. Additionally, it has been demonstrated that it is possible to reduce pixels to the 5 μm level in the same way due to the use of micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer including a group III-V compound microLED array and a Si CMOS back plane wafer including numerous IC electrode pad arrays and then assembling these wafers. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDoS to which high-resolution, high-brightness, and high-speed operating blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using engineering monolithic epitaxy wafers according to the related art using metal bonding, the patterning etching process faces even greater difficulties.

As another example, great progress has been made in solving the problem of limitations on the brightness and resolution of LEDoS to which group III-V compound microLED light sources have been recently applied, and a novel engineering monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED FAB process on the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in operation (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in operation (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in operation (2), there is a problem that defects occur due to the difficulty in ultra-fine alignment wafer bonding between the Si blanket wafer (that is, the front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 manner.

That is, although the engineering monolithic epitaxy wafer approach presented in the above-described technologies is evaluated to provide a solution that brings us one step closer to the implementation of LEDoS based on ultra-small microLEDs with pixel sizes of less than 5 μm, since there are quality and yield issues caused by the use of metals (low temperature, multi-layer) in wafer bonding, it is very difficult to manufacture high-resolution microdisplays with ultra-fine pixels smaller than 3 μm, and there are also problems with some alignment processes, new alternatives are needed.

In addition, since color filters are still applied to the vertically stacked tandem structures of conventional microdisplays so that full color is implemented, there are disadvantages in terms of color quality, process complexity, and productivity.

### RELATED ART DOCUMENTS

### Patent Document

(Patent Document 0001) Korean Laid-Open Patent Publication No. 10-2018-0009116

### SUMMARY OF THE INVENTION

The present invention is directed to solving the above-described conventional problems, and providing a light-emitting diode on silicon (LEDoS) microdisplay panel and a method of manufacturing the same, which do not require an alignment process of an LED stack and a complementary metal-oxide semiconductor (CMOS) panel electrode die through an engineering monolithic epitaxy wafer using a ceramic material when a front wafer and a back wafer are bonded.

According to an aspect of the present invention, there is provided a microdisplay panel including: a back wafer in which a plurality of complementary metal-oxide semiconductor (CMOS) panel electrode dies are aligned on an upper surface; a plurality of LED stacks aligned on the plurality of CMOS panel electrode dies; and a common electrode formed on the plurality of LED stacks, wherein each of the LED stacks includes a metal layer and a light-emitting portion stacked on the metal layer, the metal layer includes a first metal layer and a second metal layer, and the first metal layer is disposed on at least one of an upper portion and a lower portion of the second metal layer.

Also, the first metal layer may be formed of a low-melting-point metal, and the second metal layer may be formed of a noble metal.

Furthermore, the first metal layer may be formed in contact with a diffusion barrier layer.

In addition, the first metal layer and the second metal layer may be heat-treated in an oxygen (O2) atmosphere.

According to another aspect of the present invention, there is provided a method of manufacturing a microdisplay panel including: a preparation operation of preparing a front wafer including a support wafer and a light-emitting portion and a back wafer having a plurality of CMOS panel electrode dies aligned on an upper surface; a stacking operation of stacking a metal layer on at least one of the front wafer and the back wafer; a bonding operation of bonding the front wafer and the back wafer to each other through the metal layer and then removing the support wafer to stack the light-emitting portion on the back wafer; an etching operation of aligning a plurality of LED stacks on the plurality of CMOS panel electrode die by etching the stacked light-emitting portion to separate the stacked light-emitting portion into preset units; and a forming operation of forming a common electrode on the plurality of LED stacks, wherein the metal layer includes a first metal layer and a second metal layer, and in the bonding operation, the front wafer and the back wafer are bonded to each other through the metal layer so that the first metal layer is disposed on at least one of an upper portion and a lower portion of the second metal layer.

Also, the first metal layer may be formed of a low-melting-point metal, and the second metal layer may be formed of a noble metal.

Furthermore, in the stacking operation, a diffusion barrier layer may be stacked on at least one of the front wafer and the back wafer, and then the first metal layer and the second metal layer are sequentially stacked.

In addition, in the bonding operation, the first metal layer and the second metal layer may be heat-treated in an oxygen (O₂) atmosphere.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a microdisplay panel according to the related art;

FIG. 2 shows a light-emitting diode on silicon (LEDoS) development approach according to the related art;

FIG. 3 shows an approach using a engineering monolithic epitaxy wafer according to the related art;

FIG. 4 is a flowchart of a method of manufacturing a microdisplay panel according to one embodiment of the present invention;

FIG. 5 shows a process of preparing a front wafer in a p-side up form in the method of manufacturing a microdisplay panel according to one embodiment of the present invention;

FIG. 6 shows a process of preparing a front wafer in an n-side up form in the method of manufacturing a microdisplay panel according to one embodiment of the present invention;

FIG. 7 shows a process of preparing a back wafer in the method of manufacturing a microdisplay panel according to one embodiment of the present invention;

FIG. 8 shows a process of manufacturing a microdisplay panel according to the method of manufacturing a microdisplay panel according to one embodiment of the present invention; and

FIG. 9 shows a microdisplay panel according to one embodiment of the present invention.

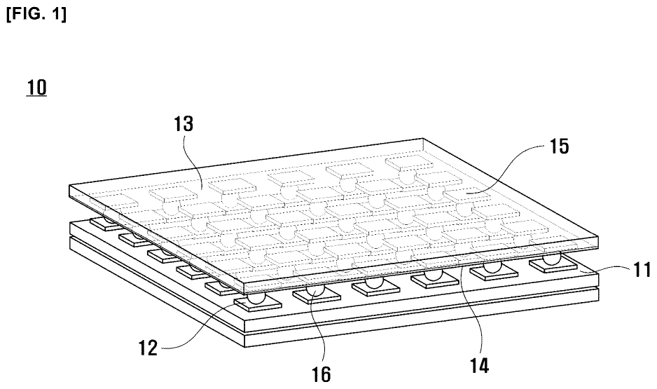

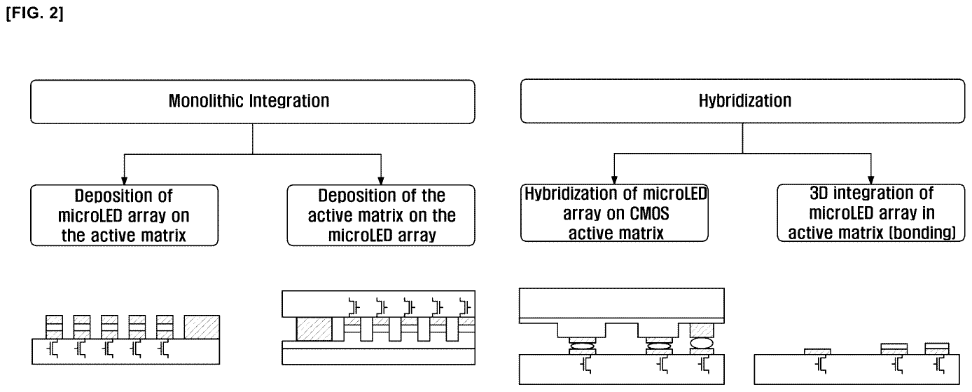

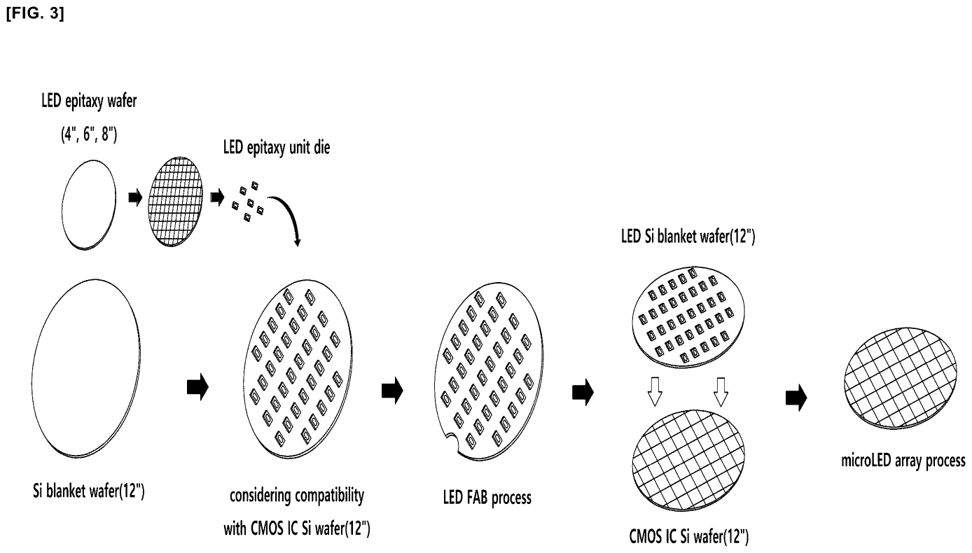

### DETAILED DESCRIPTION OF EXEMPLARY EMBODIMENTS

Hereinafter, some embodiments of the present invention will be described in detail with reference to the following exemplary drawings. In assigning reference numerals to the components of each drawing, it is important to note that the same component should have the same numeral as far as possible, even when it appears on different drawings.

Further, in describing embodiments of the present invention, detailed descriptions of relevant disclosed configurations or features are omitted when it is determined that such detailed descriptions would impede an understanding of the embodiments of the present invention.

Further, in describing the components of embodiments of the present invention, terms such as first, second, A, B, (a), (b), and the like may be used. These terms are only intended to distinguish one component from another, and the nature, order, sequence, and the like of the component are not limited by these terms.

Hereinafter, a method S100 of manufacturing a microdisplay panel according to one embodiment of the present invention will be described in detail with reference to the attached drawings.

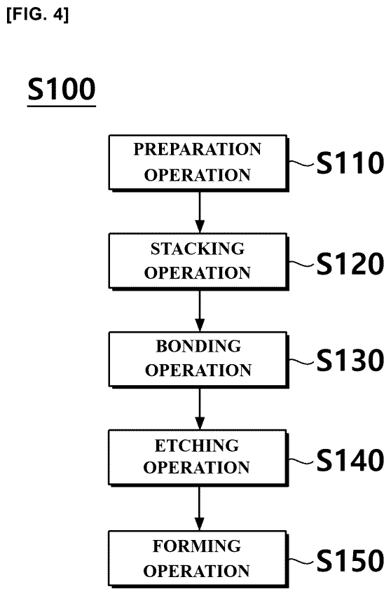

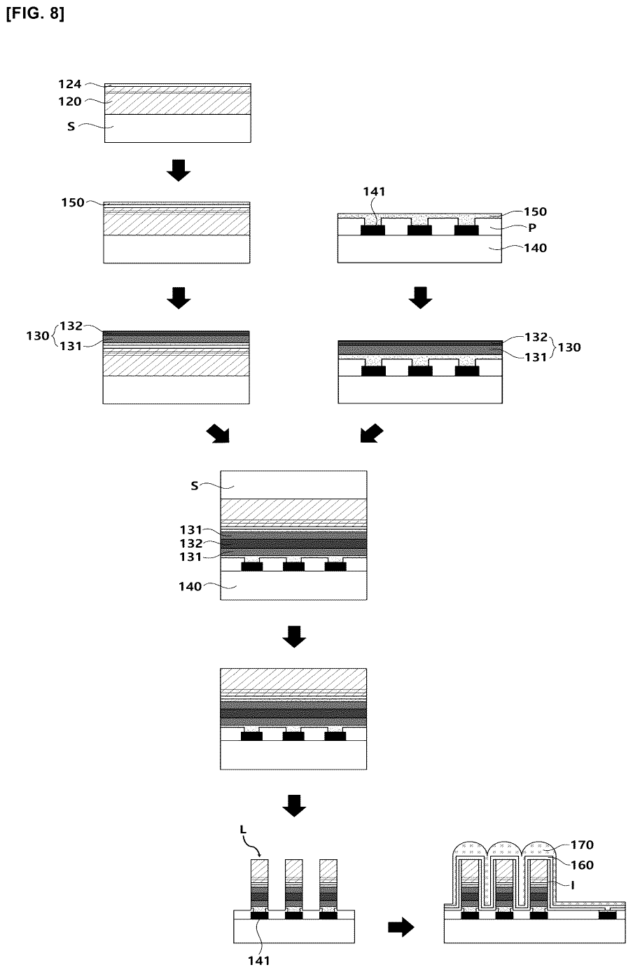

FIG. 4 is a flowchart of a method of manufacturing a microdisplay panel according to one embodiment of the present invention, and FIG. 8 shows a process of manufacturing a microdisplay panel according to the method S100 of manufacturing a microdisplay panel according to one embodiment of the present invention.

As shown in FIGS. 4 and 8, the method S100 of manufacturing a microdisplay panel according to one embodiment of the present invention may include a preparation operation S110, a stacking operation S120, a bonding operation S130, an etching operation S140, and a forming operation S150.

The preparation operation S110 is an operation of preparing a front wafer 110 and a back wafer 140.

The front wafer 110 is a front plane wafer and is intended to emit a preset color. Here, the preset color may be red, green, or blue, but is not limited thereto, and may include various other colors.

Here, the front wafer 110 may include a support wafer S and a light-emitting portion 120 that is disposed on an upper portion of the support wafer S.

The light-emitting portion 120 generates light and may emit blue light, green light, or red light. In the present invention, when the light-emitting portion 120 emits blue light or green light, binary, ternary, or quaternary compounds such as InN, InGaN, GaN, AlGaN, AlN, and AlGaInN, which are group III (Al, Ga, and In) nitride semiconductors among group III-V compound semiconductors, may be disposed at appropriate positions and in an appropriate order on an initial growth wafer G and epitaxially grown.

Particularly, in order to emit blue or green light, a high-quality group III nitride semiconductor such as InGaN with a high In composition needs to be preferentially formed on an upper portion of a group III nitride semiconductor including GaN, AlGaN, AlN, or AlGaInN, but is not limited thereto.

In addition, in the present invention, when the light-emitting portion 120 emits red light, binary, ternary, and quaternary compounds such as InP, InGaP, GaP, AlInP, AlGaP, AIP, and AlGaInP, which are group III (Al, Ga, and In) phosphide semiconductors among group III-V compound semiconductors, may be disposed at appropriate positions and in an appropriate order on an initial growth wafer G and epitaxially grown. In addition, according to recent improvements in the development of device and process technology and the value of display panel products, in the case of emitting red light, a high-quality group III nitride semiconductor such as InGaN with a high In composition of 30% or more may be preferentially formed on an upper portion of a group III nitride semiconductor including GaN, AlGaN, AlN, or AlGalnN instead of a group III phosphide semiconductor.

Particularly, in order to emit red light, a high-quality group III phosphide semiconductor such as InGaP having a high In composition needs to be preferentially formed on an upper portion of a group III phosphide semiconductor including GaP, AlInP, AlGaP, AIP, or AlGaInP, but is not limited thereto, and a group III nitride semiconductor is used as a basis for the description below.

More specifically, each of the light-emitting portions 120 may include a first semiconductor region 1201 (for example, a p-type semiconductor region), an active region 1203 (for example, multi quantum wells, MQWs), and a second semiconductor region 1202 (for example, an n-type semiconductor region) and may have a structure in which the second semiconductor region 1202, the active region 1203, and the first semiconductor region 1201 are sequentially epitaxially grown on a growth wafer G, and ultimately have an overall thickness of about 5.0 to 8.0 μm typically including a plurality of multi-layers of group III nitrides, but is not limited thereto.

Each of the first semiconductor region 1201, the active region 1203, and the second semiconductor region 1202 may be formed as a single layer or a plurality of layers. In addition, although not shown, before epitaxially growing the light-emitting portion 120 on an upper portion of the growth wafer G, necessary layers such as a buffer layer may be added to improve the quality of the epitaxially grown light-emitting portion 120. For example, the buffer layer may be configured to have a thickness of typically around 4.0 μm, including a nucleation layer NL and a compliant layer CL including an undoped semiconductor region to relieve stress and improve thin film quality. Additionally, when the growth wafer G is removed using a laser lift-off (LLO) technique, a sacrificial layer SL may be provided between the nucleation layer and the undoped semiconductor region, and a seed layer may also function as the sacrificial layer.

The second semiconductor region 1202 has a second conductivity and may be formed on the growth wafer G. The second semiconductor region 1202 may have a thickness of 2.0 to 3.5 μm.

The active region 1203 generates light by utilizing the recombination of electrons and holes and may be formed on the second semiconductor region 1202. The active region 1203 may have a thickness of several tens of nm in a plurality of layers.

The first semiconductor region 1201 has a first conductivity (p-type) and may be formed on the active region 1203. The first semiconductor region 1201 may have a thickness of several tens of nm to several μm in a plurality of layers, and the surface may have gallium polarity (Ga-polarity).

That is, the active region 1203 may be disposed between the first semiconductor region 1201 and the second semiconductor region 1202, and when holes in the first semiconductor region 1201, which is a p-type semiconductor region, and electrons in the second semiconductor region 1202, which is an n-type semiconductor region, recombine in the active region 1203, light may be generated.

Additionally, in the process of preparing the front wafer 110, an optically transparent and electrically conductive ohmic contact electrode 124 that is electrically connected to the light-emitting portion 120 by making ohmic contact with the light-emitting portion 120 may be formed on at least one of an upper surface and a lower surface of the light-emitting portion 120 that will be described below.

The support wafer S supports the light-emitting portion 120 disposed on an upper portion thereof. When an initial growth wafer G is not removed, the growth wafer G may be the support wafer S and a separate wafer bonded to remove the initial growth wafer G.

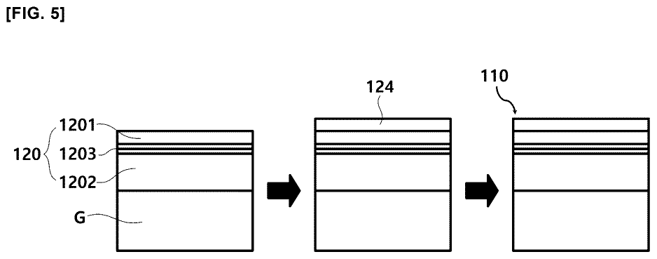

FIG. 5 shows a process of preparing a front wafer 110 in a p-side up form in the method S100 of manufacturing a microdisplay panel according to one embodiment of the present invention.

As shown in FIG. 5, the process of preparing the front wafer 110 in a p-side up form is as follows.

For blue light or green light, a front wafer 110 in a p-side up form may be prepared by sequentially epitaxially growing a second semiconductor region 1202, an active region 1203, and a first semiconductor region 1201 on a sapphire (α-phase Al2O3) growth wafer G (a GaAs growth wafer G or the like for red light) and then forming a p-type ohmic contact electrode 124 having transparent conductivity on an upper surface of the first semiconductor region 1201. In this case, the growth wafer G serves as a support wafer S, and the front wafer 110 may have a structure in which the support wafer S, a light-emitting portion 120, and the ohmic contact electrode 124 are sequentially stacked.

Meanwhile, for blue light and green light, a light-emitting portion 120 for blue light or green light may be formed on a Si growth wafer G having a (111) crystal plane instead of the sapphire (α-phase Al2O3) growth wafer G, and in this case, the Si growth wafer G may be separated and removed by a mechanical polishing technique or a chemical etching technique (chemical lift-off (CLO)).

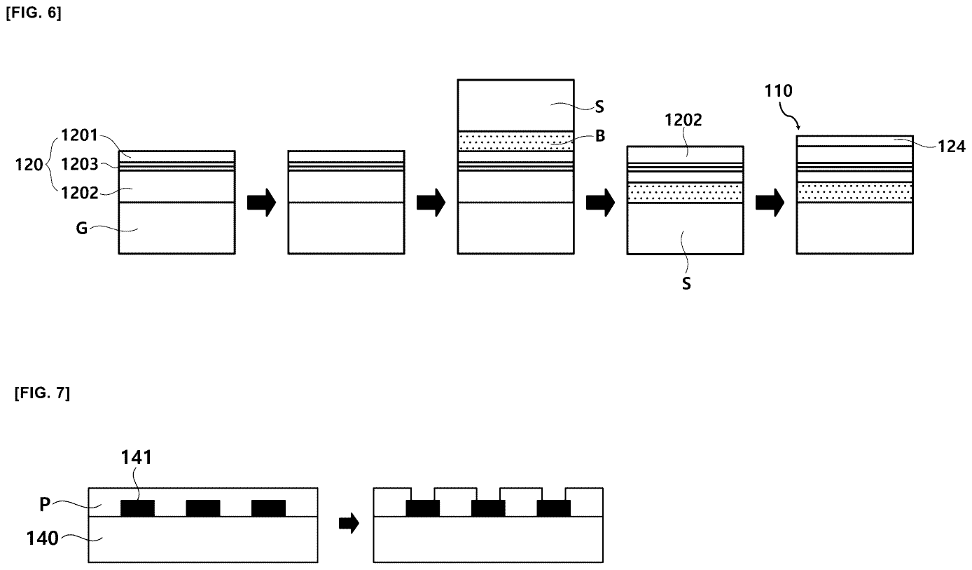

FIG. 6 shows a process of preparing a front wafer 110 in an n-side up form in the method S100 of manufacturing a microdisplay panel according to one embodiment of the present invention.

As shown in FIG. 6, the process of preparing a front wafer 110 in an n-side up form is as follows.

For blue light or green light, after sequentially epitaxially growing a second semiconductor region 1202, an active region 1203, and a first semiconductor region 1201 on a sapphire (α-phase Al2O3) growth wafer G (a GaAs growth wafer G or the like for red light), a p-type ohmic contact electrode 124 having transparent conductivity may be selectively formed on the surface of the first semiconductor region 1201, and then a support wafer S may be bonded to an upper surface through a temporary bonding layer B. Afterward, an n-side up type front wafer 110 may be prepared by separating the growth wafer G from a light-emitting portion 120 using an LLO or CLO technique, etching the second semiconductor region 1202 to reduce a thickness of the second semiconductor region 1202, and then forming an n-type ohmic contact electrode 124 having transparent conductivity on the surface of the second semiconductor region 1202 whose thickness has been reduced. In this case, the support wafer S may be formed of a Si material having a (111), (110), or (100) crystal plane, but is not limited thereto, and the front wafer 110 may have a structure in which the support wafer S, the bonding layer B, the light-emitting portion 120, and the ohmic contact electrode 124 are sequentially stacked.

Furthermore, in the present invention, the materials of the growth wafer G and/or the support wafer S may each be sapphire or silicon (Si), but the selection of the materials may be determined according to a wafer bonding method.

For example, in the case of bonding at room temperature through a surface activation process (surface activated bonding), wafers of different materials such as sapphire or silicon (Si) may be selected regardless of the thermal expansion coefficient. However, when wafer bonding is performed between the growth wafer G, the support wafer S, and the back wafer 140, in a case in which bonding is performed at a temperature of 50 °C or higher, or heat treatment (annealing) is performed at a temperature of 50 °C or higher without removing one wafer while bonding between wafers is performed, wafers of the same material need to be selected.

Meanwhile, in the above-described manufacturing process of the front wafer 110, before the ohmic contact electrode 124 is formed on the surface of the first semiconductor region 1201 or the surface of the second semiconductor region 1202, in the case where the surface of the first semiconductor region 1201 is exposed (p-side up form) or the surface of the second semiconductor region 1202 is exposed (n-side up form), the surfaces may be polished and smoothly planarized through mechanical polishing (MP) or chemical-mechanical polishing (CMP) to have a smooth surface.

In addition, the ohmic contact electrode 124 of the front wafer 110 is formed of a material having transparent conductivity. When the ohmic contact electrode 124 is formed to be in contact with the first semiconductor region 1201 which is a p-type semiconductor, the material of the ohmic contact electrode 124 may include NiO, PtO, PdO, AgO2, Au, Rh2O3, RuO2, In2O3, SnO2, ZnO, IZO, ITO, and IGZO. When the ohmic contact electrode 124 is formed to be in contact with the second semiconductor region 1202 which is an n-type semiconductor, the material of the ohmic contact electrode 124 may include In, InGa, Ga, InN, InGaN, GaN, TiN, CrN, VN, In2O3, SnO2, ZnO, IZO, ITO, and IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a CMP process for polishing and flattening the surface of the second semiconductor region 1202 before forming the ohmic contact electrode 124 having transparent conductivity.

Additionally, the surface of the ohmic contact electrode 124 formed on the front wafer 110 may also be polished and smoothed through MP or CMP.

FIG. 7 shows a process of preparing a back wafer 140 in the method S100 of manufacturing a microdisplay panel according to one embodiment of the present invention.

The back wafer 140 is an active driving IC driven by an active matrix AM method and is a CMOS backplane wafer or a CMOS panel in which a plurality of CMOS panel electrode dies 141 are arranged on an upper surface in an array. A passivation layer P may be formed on the upper surface of the back wafer 140 so that upper surfaces of the plurality of CMOS panel electrode dies 141 are not exposed, and a portion of the passivation layer P may be etched so that the plurality of CMOS panel electrode dies 141 are exposed to the outside during the process of bonding a front wafer 110.

In this case, a reflective metal may be additionally deposited on the exposed CMOS panel electrode die 141 to increase luminous efficiency. For example, when the CMOS panel electrode die 141 is formed of Cu, the reflective metal may be Ag, AgCu, AgCuPd, Al, Rh, or the like, but is not limited thereto.

In addition, the back wafer 140 may be prepared as a Si wafer having a (100) crystal plane and may be prepared as an 8-inch or 12-inch Si wafer according to a standard CMOS IC process. However, considering that a typical LED wafer (the front wafer 110) for bonding is 4 inches or 6 inches, the size of the back wafer 140 is not particularly limited.

The stacking operation S120 is an operation of stacking a metal layer 130 for strengthening adhesion on at least one of the front wafer 110 and the back wafer 140.

In this case, in the stacking operation S120, when the metal layer 130 is formed on the front wafer 110 or the back wafer 140, the diffusion barrier layer 150 (diffusion barrier layer (DBL)) may be first stacked, and then a first metal layer 131 and a second metal layer 132 may be sequentially stacked.

For example, in the stacking operation S120, the metal layer 130 for strengthening adhesion may be stacked only on the back wafer 140, and the metal layer 130 for strengthening adhesion may be stacked on both the front wafer 110 and the back wafer 140. That is, in some cases, the diffusion barrier layer 150, the first metal layer 131, and the second metal layer 132 may be omitted in the front wafer 110 of the present invention.

Specifically, in the stacking operation S120, in the case of the front wafer 110, a diffusion barrier layer 150 may be first deposited and stacked on an ohmic contact electrode 124, and then a first metal layer 131 and a second metal layer 132 may be sequentially deposited and stacked on the diffusion barrier layer 150, and in the case of the back wafer 140, a diffusion barrier layer 150 may be first deposited and stacked on the exposed CMOS panel electrode die 141 and passivation layer P, and then a first metal layer 131 and a second metal layer 132 may be sequentially deposited and stacked on the diffusion barrier layer 150.

In this case, in the stacking operation S120, it is preferable to introduce a CMP process of polishing and flattening the surface of the diffusion barrier layer 150 before depositing the first metal layer 131 on the diffusion barrier layer 150.

Meanwhile, the material of the diffusion barrier layer 150 may be formed of a transparent conductive oxide which is the same as or similar to that of the ohmic contact electrode 124, and may be formed of, for example, a TCO material such as ITO, IZO, or IGZO, but is not limited thereto.

The diffusion barrier layer 150 may serve to prevent the low-melting-point metal of the first metal layer 131 from diffusing and thus adversely affecting the CMOS panel electrode die 141 or the ohmic contact electrode 124 during bonding through a thermo-compression method in the bonding operation S130 that will be described below.

In addition, the first metal layer 131 serves to strengthen the adhesion between transparent conductive oxide materials through diffusion bonding at low temperatures, and the first metal layer 131 may be formed of a low-melting-point metal, and formed of, for example, In, Sn, Zn, or Ga, but is not limited thereto.

In addition, in the stacking operation S120, a first metal layer 131 may be deposited on a diffusion barrier layer 150, and then a second metal layer 132 may be deposited in a subsequent process. This is to prevent the surface of the first metal layer 131, which is a low-melting-point metal, from being oxidized. The second metal layer 132 may be formed of a noble metal, for example, formed of Au, Ag, or Cu, but is not limited thereto.

In addition, it is preferable that a thickness of each of the first metal layer 131 and the second metal layer 132 be as small as possible, and it is preferable that the thickness not exceed 500 nm.

The bonding operation S130 is an operation of bonding the front wafer 110 onto the back wafer 140 through the metal layer 130 and then removing the support wafer S to stack the light-emitting portion 120 on the back wafer 140.

Specifically, in the bonding operation S130, when the metal layer 130 is formed only on the back wafer 140, the front wafer 110 and the second metal layer 132 on an uppermost portion of the back wafer 140 are bonded to each other, thereby bonding the front wafer 110 onto the back wafer 140. When the metal layer 130 is formed on both the front wafer 110 and the back wafer 140, the second metal layer 132 on an uppermost portion of the front wafer 110 and the second metal layer 132 on the uppermost portion of the back wafer 140 are bonded to each other, thereby bonding the front wafer 110 onto the back wafer 140.

Afterward, the support wafer S of the front wafer 110 may be removed through LLO, CLO, or the like.

Accordingly, in the present invention, the first metal layer 131 may be disposed on at least one of an upper portion and a lower portion of the second metal layer 132, thereby strengthening adhesion at the upper portion or the lower portion of the second metal layer 132.

Here, a bonding method may be a wafer-to-wafer (W2W) or die-to-wafer (D2W) method using, for example, surface activation bonding (SAB), a fast Ar beam, plasma of an argon-containing active gas (for example, H2, O2, N2, Cl2, or the like), but is not limited thereto, and it is preferable to use a thermo-compression method that enables diffusion bonding at low temperatures.

Furthermore, after the front wafer 110 and the back wafer 140 are bonded, a heat-treatment process is essentially performed in an oxygen (O2) atmosphere at a temperature of 350 °C or lower. This is to oxidize the first metal layer 131, which is a low-melting-point metal, and the second metal layer 132, which is a noble metal, and convert these layers into an optically transparent or semi-transparent and electrically conductive material layer. Through this, the optical alignment on the CMOS panel electrode die 141 becomes easier in the etching operation S140 that will be described below, and process side effects such as redeposition in the etching operation S140 may be minimized, thereby enabling the maximization of quality and yield.

According to the above-described bonding operation S130, when using a front wafer 110 in a p-side up form, a diffusion barrier layer 150, a first metal layer 131, a second metal layer 132, a first metal layer 131, a diffusion barrier layer 150, a p-type ohmic contact electrode 124, and a light-emitting portion 120 may be sequentially stacked on the back wafer 140, and the light-emitting portion 120 may have an n-side up form. In this case, when a metal layer 130 is formed only on the back wafer 140, the first metal layer 131 and the diffusion barrier layer 150 on an upper portion of the second metal layer 132 may be omitted.

In addition, when using a front wafer 110 in an n-side up form in which a p-type ohmic contact electrode 124 is not formed, a diffusion barrier layer 150, a first metal layer 131, a second metal layer 132, a first metal layer 131, a diffusion barrier layer 150, an n-type ohmic contact electrode 124, and a light-emitting portion 120 may be sequentially stacked on a back wafer 140, and the light-emitting portion 120 may have a p-side up form. In this case, when a metal layer 130 is formed only on the back wafer 140, the first metal layer 131 and the diffusion barrier layer 150 on an upper portion of the second metal layer 132 may be omitted.

The etching operation S140 is an operation of separating the light-emitting portion 120, the ohmic contact electrode 124, the diffusion barrier layer 150, and the metal layer 130 which are stacked into preset units by etching them, thereby allowing a plurality of LED stacks L to be disposed and aligned on a plurality of CMOS panel electrode dies 141.

That is, the etching operation S140 may vertically etch the light-emitting portion 120, the ohmic contact electrode 124, the diffusion barrier layer 150, and the metal layer 130 until the surface of the back wafer 140 or an adjacent region (for example, the passivation layer P) is exposed to be arranged in an array, in other words, the plurality of LED stacks L are aligned on an upper portion of the aligned CMOS panel electrode die 141. Here, a preset unit is a pixel or sub-pixel unit and may be a width (diameter) of a plurality of LED stacks L.

In this case, in the present invention, although the metal layer 130 is used to improve adhesion, the metal layer 130 is oxidized to make the metal layer 130 transparent or semi-transparent, thereby facilitating etching for the alignment of the LED stacks L, as described above.

After the above-described etching operation S140, each of the LED stacks L disposed on the CMOS panel electrode die 141 may include the diffusion barrier layer 150, the first metal layer 131, the second metal layer 132, the first metal layer 131, the diffusion barrier layer 150, the ohmic contact electrode 124, and the light-emitting portion 120, which are sequentially stacked, and the light-emitting portion 120 may have an n-side up form or a p-side up form. In this case, when the metal layer 130 is formed only on the back wafer 140, the first metal layer 131 and the diffusion barrier layer 150 on an upper portion of the second metal layer 132 may be omitted.

The forming operation S150 is an operation of forming a pixel element by forming an insulating layer I that protects a side surface of the LED stack L, forming a common electrode 160 on the plurality of LED stacks L, and then forming a lens 170 to improve the luminous efficiency of each pixel on each of the LED stacks L through epoxy coating and development.

Here, the insulating layer I may be formed of an optically transparent and electrically insulating material to protect the LED stack L, such as SiO2, SiNx, or Al2O3, and after the insulating layer I is deposited to cover the LED stack L, the upper surface of the light-emitting portion 120 may be exposed through CMP or the like.

In addition, when the light-emitting portions 120 have an n-side up form, the common electrode 160 may be formed as a negative electrode, and when the light-emitting portions 120 have the p-side up form, the common electrode 160 may be formed as a positive electrode. Here, the common electrode 160 may be formed of a material having transparent conductivity similar to the ohmic contact electrode 124, when the common electrode 160 is a negative electrode, the material of the common electrode 160 may include In, InGa, Ga, InN, InGaN, GaN, TiN, CrN, VN, In2O3, SnO2, ZnO, IZO, ITO, and IGZO, and when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO.

In addition, the surface of the common electrode 160 may also be polished to be smooth and flat through MP or CMP, and the common electrode 160 may be formed to cover the side surface of the LED stack L on which the insulating layer I is formed and an upper surface of the LED stack L on which the light-emitting portion 120 is exposed, and may have a form connected to the CMOS panel electrode die 141 on which the LED stack L is not formed, but is not limited thereto.

Hereinafter, a microdisplay panel 100 according to one embodiment of the present invention will be described in detail with reference to the attached drawings.

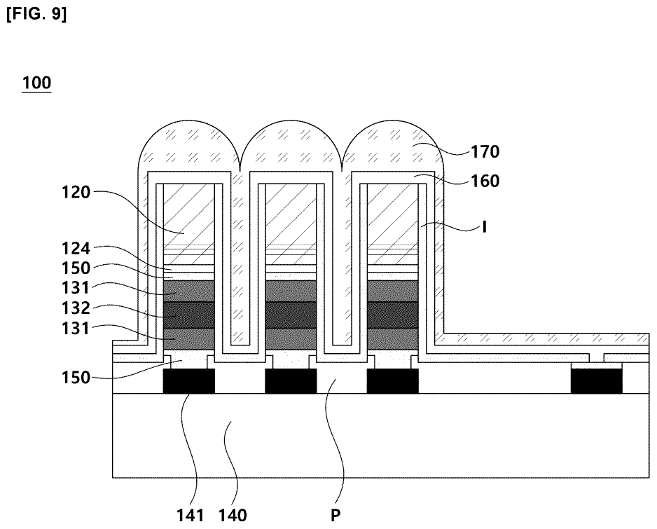

FIG. 9 shows the microdisplay panel 100 according to one embodiment of the present invention.

As shown in FIG. 9, the microdisplay panel 100 according to one embodiment of the present invention may include a back wafer 140, an LED stack L, an insulating layer I, a common electrode 160, and a lens 170.

Hereinafter, some of the overlapping content with the method S100 of manufacturing a microdisplay panel according to one embodiment of the present invention will be omitted.

The back wafer 140 is an active driving IC driven by an active matrix (AM) method, and is a CMOS wafer in which a plurality of CMOS panel electrode dies 141 are arranged on an upper surface in an array, as shown in FIG. 8. A passivation layer P may be formed on an upper surface of the back wafer 140 so that upper surfaces of a plurality of CMOS panel electrode dies 141 are not exposed, and a portion of the passivation layer P may be etched so that the plurality of CMOS panel electrode dies 141 are exposed to the outside during a process of bonding a front wafer 110.

In this case, a reflective metal may be additionally deposited on the exposed CMOS panel electrode die 141 to increase luminous efficiency. For example, when the CMOS panel electrode die 141 is formed of Cu, the reflective metal may be Ag, AgCu, AgCuPd, a Ag alloy, Al, an Al alloy, Rh, a Rh alloy, Au, or a Au alloy, but is not limited thereto.

The LED stack L is disposed on each CMOS panel electrode die 141, and may include a diffusion barrier layer 150, a first metal layer 131, a second metal layer 132, a first metal layer 131, a diffusion barrier layer 150, an ohmic contact electrode 124, and a light-emitting portion 120 that are sequentially stacked, and the light-emitting portion 120 may have an n-side up form or a p-side up form. In this case, when a metal layer 130 is formed only on the back wafer 140, the first metal layer 131 and the diffusion barrier layer 150 on an upper portion of the second metal layer 132 may be omitted.

Accordingly, in the present invention, the first metal layer 131 may be disposed on at least one of the upper portion and a lower portion of the second metal layer 132, thereby strengthening adhesion at the upper portion or the lower portion of the second metal layer 132.

Meanwhile, the material of the diffusion barrier layer 150 may be formed of a transparent conductive oxide which is the same as or similar to that of the ohmic contact electrode 124, and may be formed of a TCO material such as ITO, IZO, or IGZO, but is not limited thereto.

The diffusion barrier layer 150 serves to prevent the low-melting-point metal of the first metal layer 131 from diffusing and thus adversely affecting the CMOS panel electrode die 141 or the ohmic contact electrode 124 during bonding through a thermo-compression method.

In addition, the first metal layer 131 serves to strengthen the adhesion between transparent conductive oxide materials through diffusion bonding at low temperatures, and the first metal layer 131 may be formed of a low-melting-point metal and may be formed of, for example, In, Sn, Zn, or Ga, but is not limited thereto.

In addition, the second metal layer 132 is intended to prevent the surface of the first metal layer 131, which is a low-melting-point metal, from oxidizing before bonding, and the second metal layer 132 may be formed of a noble metal, for example, formed of Au, Ag, or Cu, but is not limited thereto.

Furthermore, the thickness of each of the first metal layer 131 and the second metal layer 132 is preferably as small as possible and is preferably no more than 500 nm.

The insulating layer I protects a side surface of the LED stack L, and the insulating layer I may be formed of a material that is optically transparent and electrically insulating to protect the LED stack L, such as SiO2, SiNx, or Al2O3.

Meanwhile, the insulating layer I may be deposited to cover the LED stack L and then etched by CMP or the like so that the insulating layer I is formed only on the side surface of the LED stack L and may have a shape such that the upper surface of the LED stack L, that is, the upper surface of the light-emitting portion 120, is exposed.

The common electrode 160 may be formed as a negative electrode when the light-emitting portions 120 are of an n-side up form and may be formed as a positive electrode when the light-emitting portions 120 are of a p-side up form. Here, the common electrode 160 may be formed of a material having transparent conductivity similar to the ohmic contact electrode 124. When the common electrode 160 is a negative electrode, the material of the common electrode 160 may include In, InGa, Ga, InN, InGaN, GaN, TiN, CrN, VN, In2O3, SnO2, ZnO, IZO, ITO, and IGZO. When the common electrode 160 is a positive electrode, the material of the common electrode 160 may include NiO, PtO, PdO, AgO2, Au, Rh2O3, RuO2, In2O3, SnO2, ZnO, IZO, ITO, and IGZO.

Meanwhile, the common electrode 160 may have a side surface of the LED stack L on which the insulating layer I is formed, and the light-emitting portion 120 is formed to cover the upper surface of the exposed LED stack L, leading to a CMOS panel electrode die 141 on which the LED stack L is not formed, but is not limited thereto.

The lens 170 is intended to improve the luminous efficiency of each pixel, and may be formed over each of the LED stacks L through epoxy coating and development.

According to the present invention, unlike the existing monolithic integration method or hybridization method having alignment issues, an engineering monolithic epitaxy wafer is first manufactured, and then a stack on the engineering monolithic epitaxy wafer is etched to separate the stack into preset units, thereby allowing a plurality of LED stacks to be aligned on a plurality of CMOS panel electrode dies. Thus, not only a small-diameter wafer of 6 inches or less but also a large-diameter wafer of 8 inches or more can be used so that the product yield can be significantly increased.

In addition, according to the present invention, since adhesion and transmittance can be significantly simultaneously improved in bonding using a transparent conductive oxide, optical alignment is easy in a subsequent pixel element formation process, and the side effects of an etching process, such as redeposition, can be minimized, thereby maximizing quality and yield.

Meanwhile, the effects of the present invention are not limited to the above-described effects and may include various effects within a range that is apparent to a person skilled in the art from the contents that will be described below.

Above, wherein all of the components comprising embodiments of the present invention have been described as being combined or operating in combination, the present invention is not necessarily limited to these embodiments. That is, any of the components may optionally operate in combination with one or more of the foregoing, provided that it is within the scope of the present invention.

In addition, terms such as “includes,” “consists of,” or “has” as used herein shall, unless specifically indicated to the contrary, be construed to mean that the component may be inherent in, and therefore may further include, other components, rather than exclude, other components. All terms, including technical or scientific terms, unless otherwise defined, shall have the same meaning as commonly understood by one of ordinary skill in the technical field to which the present invention belongs. Commonly used terms, such as those defined in the dictionary, are to be interpreted consistent with their contextual meaning in the relevant art and are not to be construed in an idealized or overly formal sense unless expressly defined in the present invention.

And the foregoing description is merely an exemplary description of the technical ideas of the present invention, and various modifications and variations will be apparent to one having ordinary knowledge in the technical field to which the present invention belongs, without departing from the essential features of the invention.

Accordingly, the embodiments disclosed in the present invention are intended to describe and not to limit the technical ideas of the present invention, and the scope of the technical ideas of the present invention is not limited by these embodiments. The scope of protection of the present invention shall be construed in accordance with the following claims, and all technical ideas within the scope thereof shall be construed to be included within the scope of the present invention.

What is claimed is:

1. A microdisplay panel comprising:
a back wafer in which a plurality of complementary metal-oxide semiconductor (CMOS) panel electrode dies are aligned on an upper surface;
a plurality of light-emitting diode (LED) stacks aligned on the plurality of CMOS panel electrode dies; and
a common electrode formed on the plurality of LED stacks,
wherein each of the LED stacks includes a metal layer and a light-emitting portion stacked on the metal layer,
the metal layer includes a first metal layer and a second metal layer, and
the first metal layer is disposed on at least one of an upper portion and a lower portion of the second metal layer.

2. The microdisplay panel of claim 1, wherein the first metal layer is formed of a low-melting-point metal, and
the second metal layer is formed of a noble metal.

3. The microdisplay panel of claim 1, wherein the first metal layer is formed in contact with a diffusion barrier layer.

4. The microdisplay panel of claim 1, wherein the first metal layer and the second metal layer are heat-treated in an oxygen (O₂) atmosphere.

5. A method of manufacturing a microdisplay panel, comprising:
a preparation operation of preparing a front wafer including a support wafer and a light-emitting portion and a back wafer having a plurality of CMOS panel electrode dies aligned on an upper surface;
a stacking operation of stacking a metal layer on at least one of the front wafer and the back wafer;
a bonding operation of bonding the front wafer and the back wafer to each other through the metal layer and then removing the support wafer to stack the light-emitting portion on the back wafer;
an etching operation of aligning a plurality of light-emitting diode (LED) stacks on the plurality of CMOS panel electrode die by etching the stacked light-emitting portion to separate the stacked light-emitting portion into preset units; and
a forming operation of forming a common electrode on the plurality of LED stacks,
wherein the metal layer includes a first metal layer and a second metal layer, and
in the bonding operation, the front wafer and the back wafer are bonded to each other through the metal layer so that the first metal layer is disposed on at least one of an upper portion and a lower portion of the second metal layer.

6. The method of claim 5, wherein the first metal layer is formed of a low-melting-point metal, and
the second metal layer is formed of a noble metal.

7. The method of claim 5, wherein, in the stacking operation, a diffusion barrier layer is stacked on at least one of the front wafer and the back wafer, and then the first metal layer and the second metal layer are sequentially stacked.

8. The method of claim 5, wherein, in the bonding operation, the first metal layer and the second metal layer are heat-treated in an oxygen (O₂) atmosphere.
